(19) United States
(12) Patent Application Publication
(10) Pub. No.: US 2023/0282570 A1
(43) Pub. Date: Sep. 7, 2023

(54) SEMICONDUCTOR STRUCTURE AND METHOD FOR FORMING SAME

(71) Applicant: Semiconductor Manufacturing International (Shanghai) Corporation, Shanghai (CN)

(72) Inventors: Jisong JIN, Shanghai (CN); Chao ZHANG, Shanghai (CN)

(73) Assignee: Semiconductor Manufacturing International (Shanghai) Corporation, Shanghai (CN)

(21) Appl. No.: 18/096,121

(22) Filed: Jan. 12, 2023

(30) Foreign Application Priority Data
Mar. 2, 2022 (CN) 202210204929.0

(51) Int. Cl. H01L 23/522; H01L 21/768

(52) U.S. Cl. CPC H01L 23/5226; H01L 21/76808; H01L 21/76805; H01L 21/76844; H01L 23/53223

(57) ABSTRACT

Semiconductor structures and methods for forming the same are provided. In one form, a semiconductor structure includes: a substrate; a bottom dielectric layer, located on the substrate; a bottom interconnect layer, located in the bottom dielectric layer; a top dielectric layer, located on the bottom dielectric layer and the bottom interconnect layer; a conductive plug, located in the top dielectric layer on a top of the bottom interconnect layer and having a bottom in direct contact with the bottom interconnect layer and a sidewall in direct contact with the top dielectric layer; a top interconnect layer, located in the top dielectric layer above the conductive plug and in contact with the conductive plug; and a top adhesion layer, located between the top interconnect layer and the top dielectric layer. By means of embodiments and implementations of the present disclosure, electrical connection performance of a semiconductor structure is optimized.

### RELATED APPLICATION

The present application claims priority to Chinese Patent Appln. No. 202210204929.0, filed Mar. 2, 2022, the entire disclosure of each of which are hereby incorporated by reference.

### TECHNICAL FIELD

The present disclosure relates to the field of semiconductor manufacturing, and in particular, to a semiconductor structure and a method for forming the same.

### BACKGROUND

A metal interconnect structure formation process is generally required during fabrication of a back end of line (BEOL) of a semiconductor device. The metal interconnect structure formation process is generally performed on a semiconductor substrate. The semiconductor substrate generally has an active region disposed thereon. The semiconductor device such as a transistor and a capacitor are formed on the active region. A plurality of conductive plugs and a plurality of metal interconnect layers are generally arranged in the metal interconnect structure, and the plurality of metal interconnect layers may be electrically connected by a conductive plug. When a latter metal interconnect layer is formed on a previous conductive plug or a latter conductive plug is formed on a previous metal interconnect layer, an interlayer dielectric layer is generally formed on the previous conductive plug or the previous metal interconnect layer. Then, a via and an interconnect trench are formed in the interlayer dielectric layer, and finally, the via and the interconnect trench are filled with metal to form the latter conductive plug or the latter metal interconnect layer.

After the via or the interconnect trench is formed, and before the via and the trench are filled with the metal, an adhesion layer is generally further formed on a bottom surface and a sidewall of the via or the interconnect trench.

However, at present, contact resistance between the conductive plug and the metal interconnect layer is relatively large.

### SUMMARY

To address the above problem the present disclosure provides semiconductor structures and methods for forming the same, so as to optimize electrical connection performance of the semiconductor structure.

To address the above problem, one form of the present disclosure provides a semiconductor structure. The semiconductor structure includes: a substrate; a bottom dielectric layer, located on the substrate; a bottom interconnect layer, located in the bottom dielectric layer; a top dielectric layer, located on the bottom dielectric layer and the bottom interconnect layer; a conductive plug, located in the top dielectric layer on a top of the bottom interconnect layer and having a bottom in direct contact with the bottom interconnect layer and a sidewall in direct contact with the top dielectric layer; a top interconnect layer, located in the top dielectric layer above the conductive plug and in contact with the conductive plug; and a top adhesion layer, located between the top interconnect layer and the top dielectric layer.

In some implementations, the semiconductor structure further includes: a bottom adhesion layer, located between the bottom interconnect layer and the bottom dielectric layer.

In some implementations, a material of the bottom adhesion layer includes at least one of tantalum, tantalum nitride, titanium, titanium nitride, cobalt, manganese, manganese oxide, ruthenium nitride, or ruthenium.

In some implementations, the semiconductor structure further includes: an etch stop layer, located between the bottom dielectric layer and the top dielectric layer and between the bottom interconnect layer and the top dielectric layer. The conductive plug further extends through the etch stop layer.

In some implementations, a material of the etch stop layer includes at least one of silicon nitride, silicon carbide, aluminum oxide, or aluminum nitride.

In some implementations, the top interconnect layer and the conductive plug are integrally formed.

In some implementations, a material of the top adhesion layer includes at least one of tantalum, tantalum nitride, titanium, titanium nitride, cobalt, manganese, manganese oxide, ruthenium nitride, or ruthenium.

In some implementations, a material of the bottom interconnect layer includes at least one of Co, W, Ru, Al, Ir, Rh, Os, Pd, Cu, Pt, Ni, Ta, TaN, Ti, or TiN. A material of the top interconnect layer includes at least one of Co, W, Ru, Al, Ir, Rh, Os, Pd, Cu, Pt, Ni, Ta, TaN, Ti, or TiN. A material of the bottom dielectric layer includes at least one of a low-k dielectric material, an ultra low-k dielectric material, silicon oxide, silicon nitride, or silicon oxynitride. A material of the top dielectric layer includes at least one of a low-k dielectric material, an ultra low-k dielectric material, silicon oxide, silicon nitride, or silicon oxynitride. A material of the conductive plug includes at least one of Co, W, Ru, Al, Ir, Rh, Os, Pd, Cu, Pt, Ni, Ta, TaN, Ti, or TiN.

Another form of the present disclosure provides a method for forming a semiconductor structure. The method includes: providing a substrate, where a bottom dielectric layer and a bottom interconnect layer located in the bottom dielectric layer are formed on the substrate, and a top surface of the bottom interconnect layer is exposed from the bottom dielectric layer; forming a top dielectric layer on the bottom dielectric layer and the bottom interconnect layer; forming an interconnect trench in a part of the top dielectric layer in thickness; forming a top adhesion layer on a bottom and a sidewall of the interconnect trench; forming a conductive via extending through the top adhesion layer and the top dielectric layer on a part of the bottom of the interconnect trench, where the bottom interconnect layer is exposed from a bottom of the conductive via; and filling the conductive via and the interconnect trench to form a conductive plug located in the conductive via and a top interconnect layer located in the interconnect trench, where a bottom of the conductive plug is in direct contact with the bottom interconnect layer, and a sidewall of the conductive plug is in direct contact with the top dielectric layer.

In some implementations, in the step of providing the substrate, a bottom adhesion layer is further formed between the bottom interconnect layer and the bottom dielectric layer.

In some implementations, the method for forming a semiconductor structure further includes: forming an etch stop layer on the bottom dielectric layer and the bottom interconnect layer after the substrate is provided and before the top dielectric layer is formed, where in the step of forming the conductive via, the conductive via extends through the top adhesion layer, the top dielectric layer, and the etch stop layer on a part of the bottom of the interconnect trench.

In some implementations, a process for forming the top adhesion layer includes one or more of an atomic layer deposition process, a physical vapor deposition (PVD) process, or a chemical vapor deposition process.

In some implementations, the step of forming the interconnect trench includes: forming a hard mask layer on the top dielectric layer, where a mask opening located above the bottom interconnect layer is formed in the hard mask layer; and etching a part of the top dielectric layer in thickness on a bottom of the mask opening by using the hard mask layer as a mask, to form the interconnect trench.

In some implementations, the step of forming the conductive via includes: filling the interconnect trench with a planarization layer; forming a patterned layer on the planarization layer, where a pattern opening located above the interconnect trench is formed in the patterned layer; removing the planarization layer, the top adhesion layer, and the top dielectric layer on a bottom of the pattern opening by using the patterned layer as a mask, to form the conductive via; and removing the patterned layer and the planarization layer.

In some implementations, the step of forming the conductive plug and the top interconnect layer includes: filling the conductive via and the interconnect trench with a conductive material, where the conductive material is further formed on the top dielectric layer; and performing planarization on the conductive material to remove the conductive material on the top dielectric layer, where the rest of the conductive material in the conductive via is configured as the conductive plug, and the rest of the conductive material in the interconnect trench is configured as the top interconnect layer.

In some implementations, a process for forming the conductive material includes one or more of a PVD process, electrochemical plating, or a chemical vapor deposition process.

Compared with the prior art, technical solutions of embodiments and implementations of the present disclosure have at least the following advantages.

In a semiconductor structure provided in forms of the present disclosure, the bottom of the conductive plug is in direct contact with the bottom interconnect layer, and the sidewall of the conductive plug is in direct contact with the top dielectric layer. Therefore, the adhesion layer between the conductive plug and the bottom interconnect layer is omitted, which is beneficial to reduce the contact resistance between the conductive plug and the bottom interconnect layer, thereby improving the electrical connection performance between the conductive plug and the bottom interconnect layer. In addition, the sidewall of the conductive plug is in direct contact with the top dielectric layer, which is also beneficial to increase a volume of the conductive plug, thereby reducing the resistance of the conductive plug and optimizing the electrical connection performance of the semiconductor structure.

In a method for forming a semiconductor structure provided in forms of the present disclosure, the top adhesion layer is formed on the bottom and the sidewall of the interconnect trench, the conductive via extending through the top adhesion layer and the top dielectric layer on a part of the bottom of the interconnect trench is formed, and the bottom interconnect layer is exposed from a bottom of the conductive via. The conductive via and the interconnect trench are filled to form the conductive plug located in the conductive via and a top interconnect layer located in the interconnect trench. The bottom of the conductive plug is in direct contact with the bottom interconnect layer, thereby omitting the adhesion layer on the bottom of the conductive via. This is beneficial to reduce the contact resistance between the conductive plug and the bottom interconnect layer, thereby improving the electrical connection performance between the conductive plug and the bottom interconnect layer. In addition, the sidewall of the conductive plug is in direct contact with the top dielectric layer, which is also beneficial to increase a volume of the conductive plug, thereby reducing the resistance of the conductive plug and optimizing the electrical connection performance of the semiconductor structure.

### BRIEF DESCRIPTION OF THE DRAWINGS

FIG. 1 is a schematic structural diagram of a semiconductor structure.

FIG. 2 is a schematic structural diagram of one form of a semiconductor structure according to the present disclosure.

FIG. 3 to FIG. 12 are schematic structural diagrams of steps in one form of a method for forming a semiconductor structure according to the present disclosure.

### DETAILED DESCRIPTION

It can be learned from the background art that contact resistance between a conductive plug and a metal interconnect layer is relatively large. The reason for relatively large contact resistance between the conductive plug and the metal interconnect layer is now analyzed in combination with a semiconductor structure.

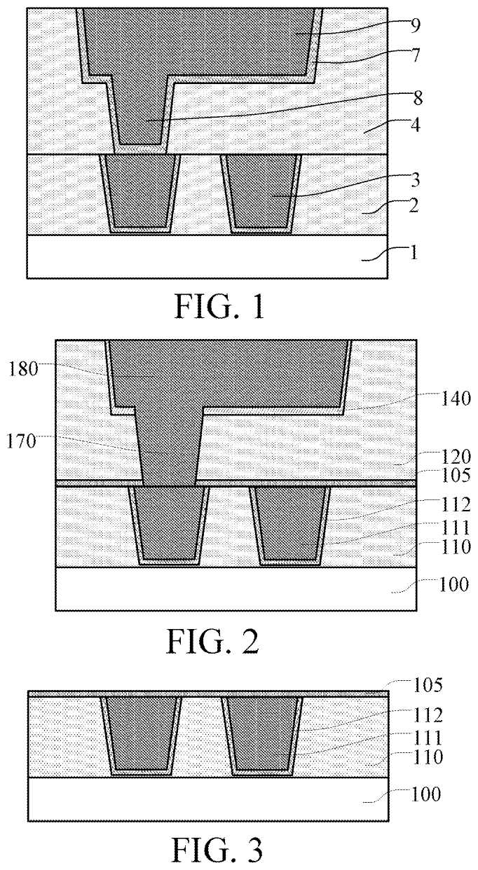

FIG. 1 is a schematic structural diagram of a semiconductor structure.

As shown in FIG. 1, the semiconductor structure includes: a substrate 1; a bottom dielectric layer 2, located on the substrate 1; a bottom interconnect layer 3, located in the bottom dielectric layer 2; a top dielectric layer 4, located on the bottom dielectric layer 2 and the bottom interconnect layer 3; a conductive plug 8, located in the top dielectric layer 4 on a top of the bottom interconnect layer 2; a top interconnect layer 9, located in the top dielectric layer 4 above the conductive plug 8 and in contact with the conductive plug 8; and an adhesion layer 7, located between the top dielectric layer 4 and the top interconnect layer 9 and between the top dielectric layer 4 and the conductive plug 8.

In the semiconductor structure, the adhesion layer 7 is located between the top dielectric layer 4 and the top interconnect layer 9 and between the top dielectric layer 4 and the conductive plug 8. Compared with materials of the conductive plug 8, the bottom interconnect layer 3, or the top interconnect layer 9, the material of the adhesion layer 7 has relatively low electrical conductivity, and the material of the adhesion layer 7 has poor electrical performance. The adhesion layer 7 is located between the conductive plug 8 and the bottom interconnect layer 3, resulting in no direct contact between the conductive plug 8 and the bottom interconnect layer 3 and relatively high contact resistance between the conductive plug 8 and the bottom interconnect layer 3. In this way, the contact performance between the conductive plug 8 and the bottom interconnect layer 3 is degraded, resulting in poor performance of the formed semiconductor structure.

In addition, the adhesion layer 7 has increasing impact on the interconnect performance of the semiconductor structure with further reduction in feature sizes of a device.

To address the technical problem, one form of the present disclosure provides a semiconductor structure, including: a substrate; a bottom dielectric layer, located on the substrate; a bottom interconnect layer, located in the bottom dielectric layer; a top dielectric layer, located on the bottom dielectric layer and the bottom interconnect layer; a conductive plug, located in the top dielectric layer on a top of the bottom interconnect layer and having a bottom in direct contact with the bottom interconnect layer and a sidewall in direct contact with the top dielectric layer; a top interconnect layer, located in the top dielectric layer above the conductive plug and in contact with the conductive plug; and a top adhesion layer, located between the top interconnect layer and the top dielectric layer.

In forms of the semiconductor structure provided by the present disclosure, the bottom of the conductive plug is in direct contact with the bottom interconnect layer, and the sidewall of the conductive plug is in direct contact with the top dielectric layer. Therefore, the adhesion layer between the conductive plug and the bottom interconnect layer is omitted, which is beneficial to reduce the contact resistance between the conductive plug and the bottom interconnect layer, thereby improving the electrical connection performance between the conductive plug and the bottom interconnect layer. In addition, the sidewall of the conductive plug is in direct contact with the top dielectric layer, which is also beneficial to increase a volume of the conductive plug, thereby reducing the resistance of the conductive plug and optimizing the performance of the semiconductor structure.

In order to make the foregoing objectives, features, and advantages of the embodiments and implementations of the present disclosure more apparent and easier to understand, specific embodiments and implementations of the present disclosure are described in detail below with reference to the accompanying drawings. Referring to FIG. 2, a schematic structural diagram of one form of a semiconductor structure according to the present disclosure is shown.

As shown in FIG. 2, in this form, the semiconductor structure includes: a substrate 100; a bottom dielectric layer 110, located on the substrate 100; a bottom interconnect layer 111, located in the bottom dielectric layer 110; a top dielectric layer 120, located on the bottom dielectric layer 110 and the bottom interconnect layer 111; a conductive plug 170, located in the top dielectric layer 120 on a top of the bottom interconnect layer 111 and having a bottom in direct contact with the bottom interconnect layer 111 and a sidewall in direct contact with the top dielectric layer 120; a top interconnect layer 180, located in the top dielectric layer 120 above the conductive plug 170 and in contact with the conductive plug 170; and a top adhesion layer 140, located between the top interconnect layer 180 and the top dielectric layer 120.

The substrate 100 is configured to provide a process platform for formation of the semiconductor structure.

In some implementations, a semiconductor device such as a transistor and a capacitor may be formed on the substrate 100, and functional structures such as a resistive structure and a conductive structure may further be formed on the substrate 100.

In some implementations, the bottom dielectric layer 110 is an inter metal dielectric (IMD) layer. The bottom dielectric layer 110 is configured to achieve electrical isolation between adjacent interconnect lines in a back end of line (BEOL) process.

Specifically, in some implementations, the bottom dielectric layer 110 is configured to electrically isolate adjacent bottom interconnect layers 111.

A material of the bottom dielectric layer 110 is an insulating dielectric material. In some implementations, the material of the bottom dielectric layer 110 includes one or more of a low-k dielectric material, an ultra low-k dielectric material, silicon oxide, silicon nitride, or silicon oxynitride.

In some implementations, the material of the bottom dielectric layer 110 is an ultra low-k dielectric material, which is beneficial to reduce parasitic capacitance between BEOL interconnect structures, thereby reducing a BEOL RC delay. Specifically, the ultra low-k dielectric material may be SiOCH.

In some implementations, the bottom dielectric layer 110 is a single-layer structure by way of example. In other implementations, the bottom dielectric layer may further be a multi-layer structure.

The bottom interconnect layer 111 is electrically connected to the substrate 100. For example, the bottom interconnect layer 111 is electrically connected to a transistor in the substrate 100, so that the transistor is electrically connected to an external circuit or other interconnect structures.

A top surface of the bottom interconnect layer 111 is exposed from the bottom dielectric layer 110, so that the conductive plug 170 can come into contact with the bottom interconnect layer 111 to realize electrical connection between the conductive plug 170 and the bottom interconnect layer 111.

In some implementations, the bottom interconnect layer 111 is formed by metal wires. A material of the bottom interconnect layer 111 is a conductive material, including one or more of Co, W, Ru, Al, Ir, Rh, Os, Pd, Cu, Pt, Ni, Ta, TaN, Ti, or TiN.

As an example, the bottom interconnect layer 111 is a single-layer structure and is made of Co. Relatively low resistivity of Co can alleviate the signal delay of a BEOL RC, increase a processing speed of a chip, and also reduce the resistance of the bottom interconnect layer 111, thereby reducing power consumption and improving the performance of the semiconductor structure.

In other implementations, the bottom interconnect layer may further be a multi-layer structure.

In some implementations, the semiconductor structure further includes a bottom adhesion layer 112, located between the bottom interconnect layer 111 and the bottom dielectric layer 110.

The bottom adhesion layer 112 is configured to improve the adhesion between the bottom interconnect layer 111 and the bottom dielectric layer 110. In other implementations, the bottom adhesion layer can further be configured as a diffusion barrier layer, to reduce a probability of the material of the bottom interconnect layer diffusing into the bottom dielectric layer, thereby alleviating the problem of electromigration (EM).

In some implementations, a material of the bottom adhesion layer 112 includes one or more of tantalum, tantalum nitride, titanium, titanium nitride, cobalt, manganese, manganese oxide, ruthenium nitride, or ruthenium. In some implementations, the material of the bottom adhesion layer 112 is tantalum nitride.

In some implementations, the bottom dielectric layer 110 and the bottom interconnect layer 111 are located on the substrate 100 by way of example. In an actual process, one or more dielectric layers can further be formed between the bottom dielectric layer 110 and the substrate 100, and an interconnect layer and/or a conductive plug can be formed in each dielectric layer.

The top dielectric layer 120 is also an IMD layer. The top dielectric layer 120 is configured to achieve electrical isolation between the conductive plugs 170 and electrical isolation between the top interconnect layers 180.

A material of the top dielectric layer 120 is an insulating dielectric material. In some implementations, the material of the top dielectric layer 120 is one or more of a low-k dielectric material, an ultra low-k dielectric material, silicon oxide, silicon nitride, or silicon oxynitride.

As an example, the material of the top dielectric layer 120 is an ultra low-k dielectric material, thereby reducing parasitic capacitance between BEOL interconnect structures, and reducing the BEOL RC delay. Specifically, the ultra low-k dielectric material may be SiOCH.

In some implementations, the top dielectric layer 120 is a single-layer structure by way of example. In other implementations, the top dielectric layer may further be a multi-layer structure.

The conductive plug 170 is configured to realize electrical connection between the bottom interconnect layer 111 and other interconnect structures or the external circuit. Specifically, in some implementations, the conductive plug 170 is configured to achieve electrical connection between the bottom interconnect layer 111 and the top interconnect layer 180.

The bottom of the conductive plug 170 is in direct contact with the bottom interconnect layer 111, and the sidewall of the conductive plug 170 is in direct contact with the top dielectric layer 120. Therefore, the adhesion layer between the conductive plug 170 and the bottom interconnect layer 111 is omitted, which is beneficial to reduce the contact resistance between the conductive plug 170 and the bottom interconnect layer 111, thereby improving the electrical connection performance between the conductive plug 170 and the bottom interconnect layer 111. In addition, the sidewall of the conductive plug 170 is in direct contact with the top dielectric layer 120, which is also beneficial to increase a volume of the conductive plug 170, thereby reducing the resistance of the conductive plug 170 and optimizing the performance of the semiconductor structure.

It should be noted that, in the field of semiconductors, a contact area between the conductive plug 170 and the top dielectric layer 120 is less than a contact area between the top interconnect layer 180 and the top dielectric layer 120. Therefore, even if no adhesion layer is arranged between the conductive plug 170 and the top dielectric layer 120, the mechanical strength of the structure formed by the top interconnect layer 180 and the conductive plug 170 can also be ensured, and the adhesion between the structure formed by the top interconnect layer 180 and the conductive plug 170 and the top dielectric layer 120 can be ensured.

In some implementations, a material of the conductive plug 170 includes one or more of Co, W, Ru, Al, Ir, Rh, Os, Pd, Cu, Pt, Ni, Ta, TaN, Ti, or TiN.

In some implementations, the material of the conductive plug 170 is Co, and Co has low resistivity, which is beneficial to reduce the resistance of the conductive plug 170, thereby reducing power consumption. In addition, the probability of Co diffusing into the dielectric material is low. Therefore, when no diffusion barrier layer is arranged between the conductive plug 170 and the top dielectric layer 120, the probability of EM occurring in the conductive plug 170 is also low, thereby ensuring the reliability of the semiconductor structure.

The top interconnect layer 180 is configured to achieve electrical connection between the conductive plug 170 and the external circuit or other interconnect structures.

In some implementations, the top interconnect layer 180 and the conductive plug 170 are integrally formed, which improves the mechanical strength of the top interconnect layer 180 and the conductive plug 170. In addition, the resistance of the top interconnect layer 180 and the conductive plug 170 is reduced, and the contact resistance between the top interconnect layer 180 and the conductive plug 170 is also reduced. In this way, the contact performance between the top interconnect layer 180 and the conductive plug 170 is improved, thereby increasing a signal response speed between the top interconnect layer 180 and the conductive plug 170.

A material of the top interconnect layer 180 is the conductive material. In some implementations, a material of the top interconnect layer includes one or more of Co, W, Ru, Al, Ir, Rh, Os, Pd, Cu, Pt, Ni, Ta, TaN, Ti, or TiN.

In some implementations, the top interconnect layer 180 is made of the same material as the conductive plug 170. The material of the top interconnect layer 180 is Co.

In some implementations, the conductive plug 170 and the top interconnect layer 180 are single-layer structures by way of example. In other implementations, according to actual process requirements, the conductive plug and the top interconnect layer may also be a multi-layer structure, and the materials of the conductive plug and the top interconnect layer may include a plurality of conductive materials.

The top adhesion layer 140 is configured to improve the adhesion between the top interconnect layer 180 and the top dielectric layer 120, to enhance the mechanical strength of the top interconnect layer 180, and reduce a probability of the top interconnect layer 180 falling off, thereby improving the reliability of the semiconductor structure.

In other implementations, the top adhesion layer can further be used as a diffusion barrier layer to reduce the probability of the material of the top interconnect layer diffusing into the top dielectric layer, thereby alleviating the problem of EM. In addition, the top adhesion layer is further configured to prevent impurities such as a carbon atom and an oxygen atom in the top dielectric layer from diffusing to the top interconnect layer and a middle. The above two aspects are both beneficial to improve the reliability of the semiconductor structure.

In some implementations, a material of the top adhesion layer 140 includes one or more of tantalum, tantalum nitride, titanium, titanium nitride, cobalt, manganese, manganese oxide, ruthenium nitride, or ruthenium. In some implementations, the material of the top adhesion layer 140 is titanium nitride.

In some implementations, the semiconductor structure further includes an etch stop layer 105, located between the bottom dielectric layer 110 and the top dielectric layer 120 and between the bottom interconnect layer 111 and the top dielectric layer 120.

The etch stop layer 105 is configured to define a position at which etching stops during formation of the conductive plug 170, to reduce the probability of causing damage to the bottom interconnect layer 111 in the process steps of forming the conductive plug 170. Correspondingly, in some implementations, the conductive plug 170 further extends through the etch stop layer 105.

A material having an etching selectivity ratio to that of the bottom dielectric layer 110 and the top dielectric layer 120 is selected as a material of the etch stop layer 105. In some implementations, the material of the etch stop layer 105 includes one or more of silicon nitride, silicon carbide, aluminum oxide, or aluminum nitride.

Accordingly, the present disclosure further provides a method for forming a semiconductor structure. FIG. 3 to FIG. 12 are schematic structural diagrams of steps in one form of a method for forming a semiconductor structure according to the present disclosure.

The method for forming a semiconductor structure in this form is described in detail below with reference to the accompanying drawings.

Referring to FIG. 3, a substrate 100 is provided. A bottom dielectric layer 110 and a bottom interconnect layer 111 located in the bottom dielectric layer 110 are formed on the substrate 100. A top surface of the bottom interconnect layer 111 is exposed from the bottom dielectric layer 110.

The substrate 100 is configured to provide a process platform for the subsequent process.

In some implementations, a semiconductor device such as a transistor and a capacitor may be formed on the substrate 100, and functional structures such as a resistive structure and a conductive structure may further be formed on the substrate 100.

In some implementations, the bottom dielectric layer 110 is an IMD layer. The bottom dielectric layer 110 is configured to achieve electrical isolation between adjacent interconnect lines in the BEOL process.

Specifically, the bottom dielectric layer 110 is configured to electrically isolate adjacent bottom interconnect layers 111.

A material of the bottom dielectric layer 110 is an insulating dielectric material. In some implementations, the material of the bottom dielectric layer 110 includes one or more of a low-k dielectric material, an ultra low-k dielectric material, silicon oxide, silicon nitride, or silicon oxynitride.

In some implementations, the material of the bottom dielectric layer 110 is an ultra low-k dielectric material, thereby reducing parasitic capacitance between BEOL interconnect structures, and reducing the BEOL RC delay. Specifically, the ultra low-k dielectric material may be SiOCH.

In some implementations, the bottom dielectric layer 110 is a single-layer structure by way of example. In other implementations, the bottom dielectric layer may further be a multi-layer structure.

The bottom interconnect layer 111 is electrically connected to the substrate 100. For example, the bottom interconnect layer 111 is electrically connected to a transistor in the substrate 100, so that the transistor is electrically connected to an external circuit or other interconnect structures.

The top surface of the bottom interconnect layer 111 is exposed from the bottom dielectric layer 110, to subsequently form an interconnect structure electrically connected to the bottom interconnect layer 111.

In some implementations, the bottom interconnect layer 111 is formed by metal wires. A material of the bottom interconnect layer 111 is a conductive material. The material of the bottom interconnect layer includes one or more of Co, W, Ru, Al, Ir, Rh, Os, Pd, Cu, Pt, Ni, Ta, TaN, Ti, or TiN.

As an example, the bottom interconnect layer 111 is a single-layer structure and is made of Co. Co has relatively low resistivity, which is beneficial to improve the signal delay of the BEOL RC and increase the processing speed of a chip. In addition, the resistance of the bottom interconnect layer 111 can also be reduced, and power consumption is accordingly reduced, thereby improving the performance of the semiconductor structure.

In other implementations, the bottom interconnect layer may further be a multi-layer structure.

In some implementations, a bottom adhesion layer 112 is further formed between the bottom interconnect layer 111 and the bottom dielectric layer 110.

The bottom adhesion layer 112 is configured to improve the adhesion between the bottom interconnect layer 111 and the bottom dielectric layer 110. In other implementations, the bottom adhesion layer can further be configured as a diffusion barrier layer, to reduce a probability of the material of the bottom interconnect layer diffusing into the bottom dielectric layer, thereby alleviating the problem of EM.

In some implementations, a material of the bottom adhesion layer 112 includes one or more of tantalum, tantalum nitride, titanium, titanium nitride, cobalt, manganese, manganese oxide, ruthenium nitride, or ruthenium. In some implementations, the material of the bottom adhesion layer 112 is tantalum nitride.

In some implementations, the bottom dielectric layer 110 and the bottom interconnect layer 111 are formed on the substrate 100 by way of example. In an actual process, one or more dielectric layers can further be formed between the bottom dielectric layer 110 and the substrate 100, and an interconnect line or a conductive plug can be formed in each dielectric layer.

Still referring to FIG. 3, the method for forming a semiconductor structure further includes: forming an etch stop layer 105 on the bottom dielectric layer 110 and the bottom interconnect layer 111 after the substrate 100 is provided.

The etch stop layer 105 is configured to define a position at which etching stops during subsequent formation of the conductive via, to reduce the probability of causing damage to the bottom interconnect layer 111 in the process steps of forming the conductive via.

A material having an etching selectivity ratio to that of the bottom dielectric layer 110 and the top dielectric layer 120 is selected as a material of the etch stop layer 105. In some implementations, the material of the etch stop layer 105 includes one or more of silicon nitride, silicon carbide, aluminum oxide, or aluminum nitride.

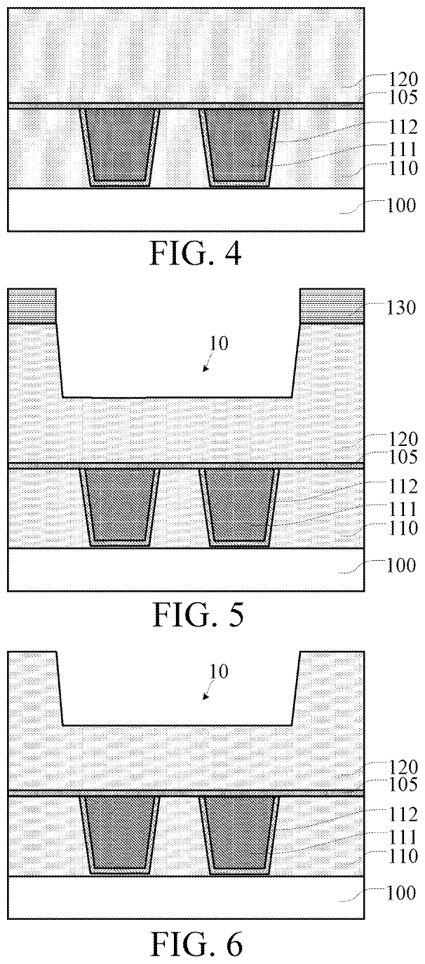

Referring to FIG. 4, the top dielectric layer 120 is formed on the bottom dielectric layer 110 and the bottom interconnect layer 111.

The subsequent steps further include: forming an interconnect trench in the top dielectric layer 120; forming a conductive via extending through the top dielectric layer 120 on a part of a bottom of the interconnect trench; and forming a conductive plug located in the conductive via and a top interconnect layer located in the interconnect trench.

The top dielectric layer 120 is an IMD layer and is configured to achieve electrical isolation between the conductive plugs and electrical isolation between the top interconnect layers.

A material of the top dielectric layer 120 is an insulating dielectric material. In some implementations, the material of the top dielectric layer 120 is one or more of a low-k dielectric material, an ultra low-k dielectric material, silicon oxide, silicon nitride, or silicon oxynitride.

As an example, the material of the top dielectric layer 120 is an ultra low-k dielectric material, thereby reducing parasitic capacitance between BEOL interconnect structures, and reducing the BEOL RC delay. Specifically, the ultra low-k dielectric material may be SiOCH.

In some implementations, the top dielectric layer 120 is a single-layer structure by way of example. In other implementations, the top dielectric layer may further be a multi-layer structure.

In some implementations, the top dielectric layer 120 is formed by using a deposition process (for example, a chemical vapor deposition process).

Referring to FIG. 5, an interconnect trench 10 in a part of the top dielectric layer 120 in thickness is formed. The interconnect trench 10 is configured to provide a space for forming the top interconnect layer.

In some implementations, the step of forming the interconnect trench 10 includes: forming a hard mask layer 130 on the top dielectric layer 120, where a mask opening (not marked) located above the bottom interconnect layer 111 is formed in the hard mask layer 130; and etching a part of the top dielectric layer 120 in thickness on a bottom of the mask opening by using the hard mask layer 130 as a mask, to form the interconnect trench 10.

In some implementations, the hard mask layer 130 is a metal hard mask layer, and the hard mask layer 130 is configured as an etching mask for forming the interconnect trench 10.

In some implementations, a material of the hard mask layer 130 is titanium nitride.

The mask opening is configured to define a shape, a position, and a size of the interconnect trench.

In some implementations, by using a dry etching process, for example, an anisotropic dry etching process, a part of the top dielectric layer 120 in thickness on a bottom of the mask opening is etched to form the interconnect trench 10.

The anisotropic dry etching process has the anisotropic etching characteristics, which is beneficial to improve the cross-sectional controllability of etching, and is correspondingly beneficial to improve the cross-sectional appearance quality of the interconnect trench 10, and also facilitates accurate control of a depth of the interconnect trench 10.

Referring to FIG. 6, after the interconnect trench 10 is formed, the method for forming a semiconductor structure further includes: removing the hard mask layer 130 to expose the top surface of the top dielectric layer 120.

The subsequent steps further include: forming a top interconnect layer in the interconnect trench 10. The forming the top interconnect layer generally includes steps of forming, on the top dielectric layer 120, a conductive material filling the interconnect trench 10, and removing the conductive material higher than the top dielectric layer 120. In some implementations, the hard mask layer 130 is removed to expose the top surface of the top dielectric layer 120. Therefore, the conductive material is only required to be filled in the interconnect trench 10 formed in a part of the top dielectric layer 120 in thickness, and is not required to be filled in a groove surrounded by the hard mask layer 130. In this way, the thickness of the conductive material that is required to be filled can be reduced, thereby improving the filling capability of the conductive material in the interconnect trench 10, and improving formation quality of the top interconnect layer.

In some implementations, the hard mask layer 130 is removed using a dry etching process. In other implementations, the hard mask layer may further be removed using a wet etching process or a combination of wet etching and dry etching.

In some implementations, removing the hard mask layer after the interconnect trench 10 is formed is used as an example. In other implementations, according to actual requirements, after the interconnect trench is formed, the hard mask layer may further be retained.

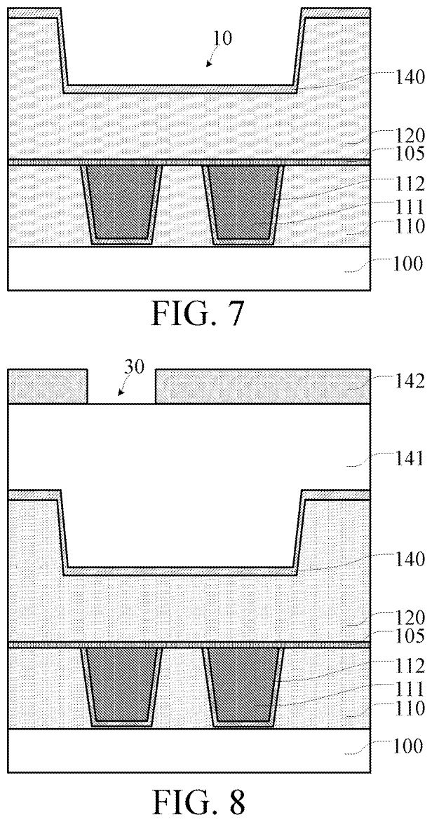

Referring to FIG. 7, a top adhesion layer 140 is formed on a bottom and a sidewall of the interconnect trench 10.

The top adhesion layer 140 is configured to improve the adhesion between the top interconnect layer 180 and the top dielectric layer 120, to enhance the mechanical strength of the top interconnect layer 180, and reduce a probability of the top interconnect layer 180 falling off, thereby improving the reliability of the semiconductor structure.

In other implementations, the top adhesion layer can further be used as a diffusion barrier layer to reduce the probability of the material of the top interconnect layer diffusing into the top dielectric layer, thereby alleviating the problem of EM. In addition, the top adhesion layer is further configured to prevent impurities such as a carbon atom and an oxygen atom in the top dielectric layer from diffusing to the top interconnect layer and a middle. The above two aspects are both beneficial to improve the reliability of the semiconductor structure.

In some implementations, a material of the top adhesion layer 140 includes one or more of tantalum, tantalum nitride, titanium, titanium nitride, cobalt, manganese, manganese oxide, ruthenium nitride, or ruthenium. In some implementations, the material of the top adhesion layer 140 is titanium nitride.

In some implementations, the top adhesion layer 140 is formed on the bottom and the sidewall of the interconnect trench 10 and the top surface of the top dielectric layer 120.

In some implementations, a process for forming the top adhesion layer 140 includes one or more of an atomic layer deposition process, a physical vapor deposition (PVD) process, or a chemical vapor deposition process.

As an example, the top adhesion layer 140 is formed by using the PVD process. The PVD process has low costs and high compatibility with the BEOL interconnect process. Specifically, the PVD process may be a sputtering process, or the like.

Referring to FIG. 8 to FIG. 10, a conductive via 20 extending through the top adhesion layer 140 and the top dielectric layer 120 on a part of the bottom of the interconnect trench 10 is formed. The bottom interconnect layer 111 is exposed from a bottom of the conductive via 20.

The conductive via 20 is configured to provide a space for forming the conductive plug.

The conductive via 20 is in communication with the interconnect trench 10, so as to achieve electrical connection between the conductive plug and the top interconnect layer that are subsequently formed.

In some implementations, the conductive via 20 extends through the top adhesion layer 140, the top dielectric layer 120, and the etch stop layer 105 on a part of a bottom of the interconnect trench 10.

In some implementations, the step of forming the conductive via 20 includes filling the interconnect trench 10 with a planarization layer 141, as shown in FIG. 8.

The planarization layer 141 is configured to provide a flat surface for forming a patterned layer, so as to improve pattern quality and dimensional accuracy of the patterned layer.

In some implementations, a material of the planarization layer 141 includes spin-on-carbon (SOC). The filling performance of the SOC is desirable, and the forming process is simple.

As shown in FIG. 8, a patterned layer 142 is formed on the planarization layer 141, and a pattern opening 30 located above the interconnect trench 10 is formed in the patterned layer 142.

The patterned layer 142 is configured as an etching mask for forming the conductive via.

In some implementations, a material of the patterned layer 142 includes photoresist. The patterned layer 142 may be formed by a photolithography process such as photoresist coating, exposure, development, and the like.

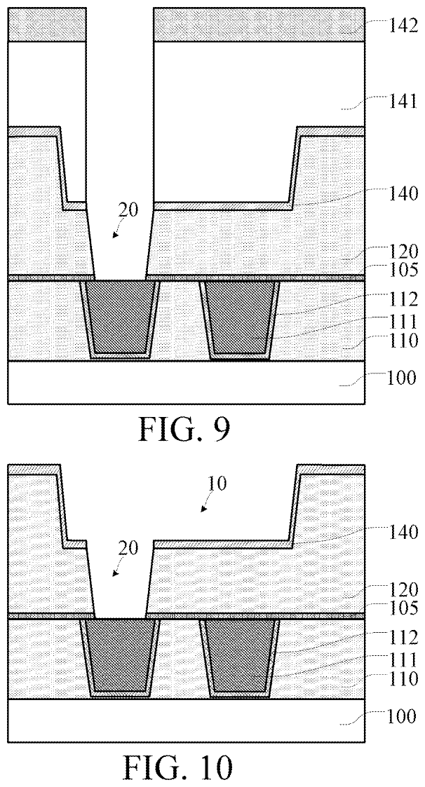

As shown in FIG. 9, the patterned layer 142 is used as the mask, and the planarization layer 141, the top adhesion layer 140, and the top dielectric layer 120 on a bottom of the pattern opening 30 are removed to form the conductive via 20.

In some implementations, by using a dry etching process, for example, an anisotropic dry etching process, the planarization layer 141, the top adhesion layer 140, and the top dielectric layer 120 are successively etched along the pattern opening 30.

Specifically, by adjusting a type of etching gas and an etching parameter, in a same reaction chamber, the planarization layer 141, the top adhesion layer 140, and the top dielectric layer 120 are successively etched.

With reference to FIG. 10, after the conductive via 20 is formed, the patterned layer 142 and the planarization layer 141 are removed, to expose the interconnect trench 10 and the conductive via 20. Specifically, the patterned layer 142 and the planarization layer 141 are removed by using an ashing process or a wet stripping process.

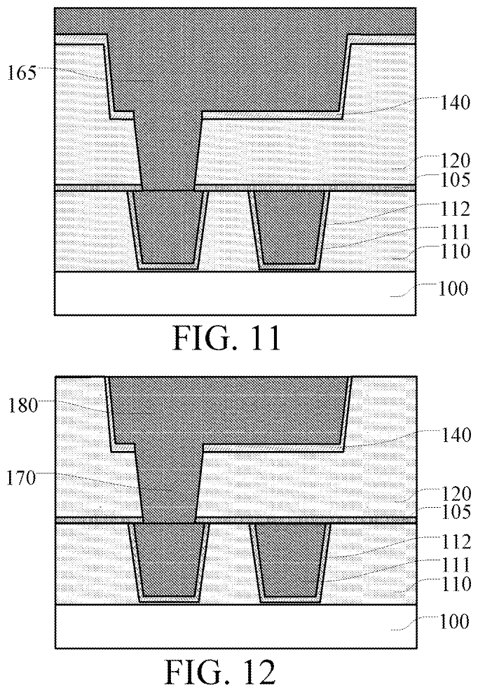

Referring to FIG. 11 and FIG. 12, the conductive via 20 and the interconnect trench 10 are filled to form a conductive plug 170 in the conductive via 20 and a top interconnect layer 180 in the interconnect trench 20. A bottom of the conductive plug 170 is in direct contact with the bottom interconnect layer 111, and a sidewall of the conductive plug 170 is in direct contact with the top dielectric layer 120.

The bottom of the conductive plug 170 is in direct contact with the bottom interconnect layer 111, thereby omitting the adhesion layer on the bottom of the conductive via 20, which is beneficial to reduce the contact resistance between the conductive plug 170 and the bottom interconnect layer 111, thereby improving the electrical connection performance between the conductive plug 170 and the bottom interconnect layer 111. In addition, the sidewall of the conductive plug 170 is in direct contact with the top dielectric layer 120, which is also beneficial to increase a volume of the conductive plug 170, thereby reducing the resistance of the conductive plug 170 and optimizing the performance of the semiconductor structure.

It should be noted that, in the field of semiconductors, a contact area between the conductive plug 170 and the top dielectric layer 120 is less than a contact area between the top interconnect layer 180 and the top dielectric layer 120. Therefore, even if no adhesion layer is arranged between the conductive plug 170 and the top dielectric layer 120, the mechanical strength of the structure formed by the top interconnect layer 180 and the conductive plug 170 can also be ensured, and the adhesion between the structure formed by the top interconnect layer 180 and the conductive plug 170 and the top dielectric layer 120 can be ensured.

The conductive plug 170 is configured to realize electrical connection between the bottom interconnect layer 111 and other interconnect structures or the external circuit. Specifically, the conductive plug 170 is configured to achieve electrical connection between the bottom interconnect layer 111 and the top interconnect layer 180.

In some implementations, a material of the conductive plug 170 includes one or more of Co, W, Ru, Al, Ir, Rh, Os, Pd, Cu, Pt, Ni, Ta, TaN, Ti, or TiN.

In some implementations, the material of the conductive plug 170 is Co, and Co has low resistivity, which is beneficial to reduce the resistance of the conductive plug 170, thereby reducing power consumption. In addition, the probability of Co diffusing into the dielectric material is low. Therefore, when no diffusion barrier layer is arranged between the conductive plug 170 and the top dielectric layer 120, the probability of EM occurring in the conductive plug 170 is also low, thereby ensuring the reliability of the semiconductor structure.

The top interconnect layer 180 is configured to achieve electrical connection between the conductive plug 170 and the external circuit or other interconnect structures.

In some implementations, the conductive via 20 is in communication with the interconnect trench 10. As a result, the conductive plug 170 and the top interconnect layer 180 are integral structures, which improves mechanical strength of the top interconnect layer 180 and the conductive plug 170. In addition, the structure is not only beneficial to reduce the resistance of the top interconnect layer 180 and the conductive plug 170, but also beneficial to reduce the contact resistance between the top interconnect layer 180 and the conductive plug 170. Therefore, the contact performance between the top interconnect layer 180 and the conductive plug 170 is improved, and a signal response speed between the top interconnect layer 180 and the conductive plug 170 is further improved.

A material of the top interconnect layer 180 is the conductive material. In some implementations, a material of the top interconnect layer includes one or more of Co, W, Ru, Al, Ir, Rh, Os, Pd, Cu, Pt, Ni, Ta, TaN, Ti, or TiN.

In some implementations, the top interconnect layer 180 is made of the same material as the conductive plug 170. The material of the top interconnect layer 180 is Co.

In some implementations, the conductive plug 170 and the top interconnect layer 180 are single-layer structures by way of example. In other implementations, according to actual process requirements, the conductive plug and the top interconnect layer may also be a multi-layer structure, and the materials of the conductive plug and the top interconnect layer may include a plurality of conductive materials.

In some implementations, the step of forming the conductive plug 170 and the top interconnect layer 180 includes: filling the conductive via 20 and the interconnect trench 10 with a conductive material 165, where the conductive material 165 is further formed on the top dielectric layer 120, as shown in FIG. 11; and performing planarization on the conductive material 165 to remove the conductive material 165 on the top dielectric layer 120, where the rest of the conductive material 165 in the conductive via 20 is configured as the conductive plug 170, and the rest of the conductive material 165 in the interconnect trench 10 is configured as the top interconnect layer 180, as shown in FIG. 12.

In some implementations, a process for forming the conductive material 165 includes one or more of the PVD process, electrochemical plating, or a chemical vapor deposition process.

In some implementations, the conductive material 165 higher than the top dielectric layer 120 is removed by using a chemical-mechanical polishing process.

It should be noted that, In some implementations, in the step of forming the conductive material 165, the conductive material 165 is formed on the top adhesion layer 140 on the top dielectric layer 120.

Therefore, the conductive material 165 and the top adhesion layer 140 higher than the top dielectric layer 120 are removed. Although the present disclosure is described above, the present disclosure is not limited to the description thereto. A person skilled in the art can make various changes and modifications without departing from the spirit and the scope of the present disclosure. Therefore, the protection scope of the present disclosure should be subject to the scope defined by the claims.

What is claimed is:

1. A semiconductor structure, comprising:
a substrate;
a bottom dielectric layer, located on the substrate;
a bottom interconnect layer, located in the bottom dielectric layer;
a top dielectric layer, located on the bottom dielectric layer and the bottom interconnect layer;
a conductive plug, located in the top dielectric layer on a top of the bottom interconnect layer and having a bottom in direct contact with the bottom interconnect layer and a sidewall in direct contact with the top dielectric layer;
a top interconnect layer, located in the top dielectric layer above the conductive plug and in contact with the conductive plug; and
a top adhesion layer, located between the top interconnect layer and the top dielectric layer.

2. The semiconductor structure according to claim 1, further comprising: a bottom adhesion layer, located between the bottom interconnect layer and the bottom dielectric layer.

3. The semiconductor structure according to claim 2, wherein a material of the bottom adhesion layer comprises at least one of tantalum, tantalum nitride, titanium, titanium nitride, cobalt, manganese, manganese oxide, ruthenium nitride, or ruthenium.

4. The semiconductor structure according to claim 1, further comprising:
an etch stop layer, located between the bottom dielectric layer and the top dielectric layer and between the bottom interconnect layer and the top dielectric layer;
wherein the conductive plug further extends through the etch stop layer.

5. The semiconductor structure according to claim 4, wherein a material of the etch stop layer comprises at least one of silicon nitride, silicon carbide, aluminum oxide, or aluminum nitride.

6. The semiconductor structure according to claim 1, wherein the top interconnect layer and the conductive plug are integrally formed.

7. The semiconductor structure according to claim 1, wherein a material of the top adhesion layer comprises at least one of tantalum, tantalum nitride, titanium, titanium nitride, cobalt, manganese, manganese oxide, ruthenium nitride, or ruthenium.

8. The semiconductor structure according to claim 1, wherein:
a material of the bottom interconnect layer comprises at least one of Co, W, Ru, Al, Ir, Rh, Os, Pd, Cu, Pt, Ni, Ta, TaN, Ti, or TiN;
a material of the top interconnect layer comprises at least one of Co, W, Ru, Al, Ir, Rh, Os, Pd, Cu, Pt, Ni, Ta, TaN, Ti, or TiN;
a material of the bottom dielectric layer comprises at least one of a low-k dielectric material, an ultra low-k dielectric material, silicon oxide, silicon nitride, or silicon oxynitride;
a material of the top dielectric layer comprises at least one of a low-k dielectric material, an ultra low-k dielectric material, silicon oxide, silicon nitride, or silicon oxynitride; and
a material of the conductive plug comprises at least one of Co, W, Ru, Al, Ir, Rh, Os, Pd, Cu, Pt, Ni, Ta, TaN, Ti, or TiN.

9. A method for forming a semiconductor structure, comprising:
providing a substrate, wherein a bottom dielectric layer and a bottom interconnect layer located in the bottom dielectric layer are formed on the substrate, and a top surface of the bottom interconnect layer is exposed from the bottom dielectric layer;
forming a top dielectric layer on the bottom dielectric layer and the bottom interconnect layer;
forming an interconnect trench in a part of the top dielectric layer in thickness;
forming a top adhesion layer on a bottom and a sidewall of the interconnect trench;
forming a conductive via extending through the top adhesion layer and the top dielectric layer on a part of the bottom of the interconnect trench, wherein the bottom interconnect layer is exposed from a bottom of the conductive via; and
filling the conductive via and the interconnect trench to form a conductive plug located in the conductive via and a top interconnect layer located in the interconnect trench, wherein a bottom of the conductive plug is in direct contact with the bottom interconnect layer, and a sidewall of the conductive plug is in direct contact with the top dielectric layer.

10. The method for forming a semiconductor structure according to claim 9, wherein in the step of providing the substrate, a bottom adhesion layer is further formed between the bottom interconnect layer and the bottom dielectric layer.

11. The method for forming a semiconductor structure according to claim 9, further comprising:
forming an etch stop layer on the bottom dielectric layer and the bottom interconnect layer after the substrate is provided and before the top dielectric layer is formed;
wherein in the step of forming the conductive via, the conductive via extends through the top adhesion layer, the top dielectric layer, and the etch stop layer on a part of the bottom of the interconnect trench.

12. The method for forming a semiconductor structure according to claim 9, wherein a process for forming the top adhesion layer comprises at least one of an atomic layer deposition process, a physical vapor deposition (PVD) process, or a chemical vapor deposition process.

13. The method for forming a semiconductor structure according to claim 9, wherein the step of forming the interconnect trench comprises:
forming a hard mask layer on the top dielectric layer, wherein a mask opening located above the bottom interconnect layer is formed in the hard mask layer; and
etching a part of the top dielectric layer in thickness on a bottom of the mask opening using the hard mask layer as a mask, to form the interconnect trench.

14. The method for forming a semiconductor structure according to claim 9, wherein the step of forming the conductive via comprises:
filling the interconnect trench with a planarization layer;
forming a patterned layer on the planarization layer, wherein a pattern opening located above the interconnect trench is formed in the patterned layer;
removing the planarization layer, the top adhesion layer, and the top dielectric layer on a bottom of the pattern opening using the patterned layer as a mask, to form the conductive via; and
removing the patterned layer and the planarization layer.

15. The method for forming a semiconductor structure according to claim 9, wherein the step of forming the conductive plug and the top interconnect layer comprises:
filling the conductive via and the interconnect trench with a conductive material, wherein the conductive material is further formed on the top dielectric layer; and
performing planarization on the conductive material to remove the conductive material on the top dielectric layer, wherein the rest of the conductive material in the conductive via is configured as the conductive plug, and the rest of the conductive material in the interconnect trench is configured as the top interconnect layer.

16. The method for forming a semiconductor structure according to claim 15, wherein a process for forming the conductive material comprises at least one of a physical vapor deposition (PVD) process, electrochemical plating, or a chemical vapor deposition process.
